(19) United States
(12) Patent Application Publication
(10) Pub. No.: US 2021/0280749 A1
(43) Pub. Date: Sep. 9, 2021

(54) Method for Producing Conversion Elements, Conversion Elements, Method for Producing a Light-Emitting Semiconductor Device, and a Light-Emitting Semiconductor Component

(71) Applicant: OSRAM OLED GmbH, Regensburg (DE)

(72) Inventors: Kathy Schmidtke, Mainburg (DE); Tobias Gebuhr, Regensburg (DE)

(21) Appl. No.: 17/266,061

(22) PCT Filed: Aug. 7, 2019
(86) PCT No.: PCT/EP2019/071242

§ 371 Date: Feb. 4, 2021

(30) Foreign Application Priority Data
Aug. 8, 2018 (DE) 10 2018 119 323.8

(51) Int. Cl. H01L 33/50; H01L 33/52; H01L 33/00

(52) U.S. Cl. CPC H01L 33/502; H01L 33/52; H01L 2933/005; H01L 2933/0041; H01L 33/005

(57) ABSTRACT

A method for producing conversion elements, a conversion element, a method for producing a light-emitting semiconductor device, and a light-emitting semiconductor device are disclosed. In an embodiment a method for producing conversion elements includes providing a sapphire substrate, forming a conversion layer on a first main surface of the sapphire substrate, and separating the sapphire substrate and the conversion layer into a plurality of conversion elements.

This patent application is a national phase filing under section 371 of PCT/EP2019/071242, filed Aug. 7, 2019, which claims the priority of German patent application 102018119323.8, filed Aug. 8, 2018, each of which is incorporated herein by reference in its entirety.

### TECHNICAL FIELD

A method for producing conversion elements is specified. Further, a conversion element is specified. Moreover, a method for producing a light-emitting semiconductor device and a light-emitting semiconductor device are specified.

### SUMMARY

Embodiments provide particularly robust and efficient conversion elements. Further embodiments provide a method for producing such conversion elements.

Other embodiments provide a light-emitting semiconductor device with improved efficiency and improved radiation behavior. Yet other embodiments provide a method for producing such a light-emitting device. In particular, such a light-emitting component may comprise a previously mentioned conversion element.

The conversion elements are configured to absorb electromagnetic radiation in a first wavelength range and to emit electromagnetic radiation in a second wavelength range. In particular, the second wavelength range comprises longer wavelengths than the first wavelength range.

According to one embodiment, the method for producing conversion elements comprises a method step a) in which a sapphire substrate is provided. The sapphire substrate is, for example, a wafer, in particular a 4″ wafer, which is formed from monocrystalline sapphire.

According to one embodiment, the method for producing conversion elements comprises a method step b) in which a conversion layer is formed on a first main surface of the sapphire substrate. The conversion layer is applied, for example, by spraying, printing or doctoring. The conversion layer comprises, for example, polysiloxane and/or polysilazane as a matrix material. At least one phosphor is embedded in the matrix material, which is configured to convert electromagnetic radiation. The phosphor may comprise an inorganic material.

For example, in forming the conversion layer, a first sublayer, a second sublayer, and a third sublayer are successively applied to each other by spraying. For example, the sublayers each comprise a thickness of 10 μm or less. The entire conversion layer comprises, for example, a thickness of 50 μm maximum. In particular, the matrix material is liquid when the sublayers are applied and is cured only after application to the sapphire substrate. For example, curing takes place by means of a condensation reaction or an addition reaction.

According to one embodiment of the method for producing conversion elements, in a method step c) the sapphire substrate and the conversion layer are separated into a plurality of conversion elements. For example, the sapphire substrate and the conversion layer are separated by means of a common sawing process. Alternatively, the sapphire substrate and the conversion layer may be separated using different separation processes. For example, an etching process, a sawing process, and/or a laser separation process are used as separation processes. In particular, the sapphire substrate and the conversion layer are separated along the lines of an imaginary regular grid, for example a rectangular grid.

According to one embodiment, the method for producing conversion elements comprises the following method steps: (a) providing a sapphire substrate; (b) forming a conversion layer on a first main surface of the sapphire substrate; and (c) separating the sapphire substrate and the conversion layer into a plurality of conversion elements.

A method for producing conversion elements described herein is based, inter alia, on the following consideration. Conversion elements must comprise a particularly high mechanical stability in order to be further processed in an encapsulation process, for example a film assisted mold process (FAM process) or an exposed-die-encapsulation process. Therefore, only ceramic-based conversion elements are usually used, which in turn means that only phosphors that can be processed in a sintering process can be used. Thus, the choice of phosphors for conversion elements that are to be further processed in an encapsulation process is severely limited.

The method for producing conversion elements described here now makes use, inter alia, of the idea of embedding the phosphor in a thin conversion layer. The sublayers are applied to the sapphire substrate by spraying, doctoring or printing. The sapphire substrate provides the necessary mechanical stability to be further processed in an encapsulation process. Advantageously, the method enables the production of conversion elements with a particularly low thickness of the conversion layer, so that heat generated during operation can be dissipated from the conversion elements particularly efficiently.

According to one embodiment, in method step c) the sapphire substrate is severed by laser cutting and the conversion layer is severed by sawing. For example, the conversion layer is severed before the sapphire substrate is severed. Advantageously, the different severing processes allow to reduce the risk of damage to the side surfaces on the sapphire substrate and to the conversion layer, respectively, resulting from the severing process.

According to one embodiment, in method step b) the conversion layer is applied with a thickness of 30 μm maximum. In particular, the thickness of the conversion layer is at most 15 μm, preferably at most 10 μm. The thickness of the conversion layer is measured perpendicular to the main extension plane of the sapphire substrate. Advantageously, the particularly low thickness of the conversion layer enables improved heat dissipation of heat generated in the conversion layer during operation.

According to one embodiment, the first main surface of the sapphire substrate comprises protrusions and/or depressions that are periodically arranged along the first main surface. For example, the sapphire substrate is a wafer, in particular a so-called patterned sapphire substrate (PSS substrate).

For example, the protrusions and/or depressions are cone-shaped, dome-shaped, or pyramid-shaped and may comprise a height and/or depth perpendicular to the first main surface between 0.65 μm and 2 μm, inclusive. For example, the protrusions and/or depressions comprise a distance of at least 2 μm and at most including 10 μm. Along the first main surface of the sapphire substrate, the protrusions and/or depressions may be arranged at the nodes of an imaginary regular grid, for example a hexagonal grid or rectangular grid. Advantageously, the protrusions and/or depressions enable improved out-coupling of electromagnetic radiation from the conversion element.

A conversion element is further specified. In particular, the conversion element can be produced by the method described above. That is, all features disclosed for the method are also disclosed for the conversion element and vice versa.

According to one embodiment, the conversion element comprises a sapphire substrate and a conversion layer which is arranged on a first main surface of the sapphire substrate, wherein the conversion layer comprises a thickness of 30 μm maximum.

According to one embodiment, the conversion element comprises a thickness of at least 120 μm. In particular, the conversion element comprises a thickness of at least 150 μm. For example, the thickness of the sapphire substrate is at least 90 μm. The thickness of the conversion element and the sapphire substrate is measured perpendicular to the main extension plane of the sapphire substrate. Advantageously, such a conversion element comprises a particularly high mechanical stability.

According to one embodiment, the conversion element comprises side surfaces, wherein the side surfaces comprise traces of a singulation process. In particular, the side surfaces of the conversion element are surfaces which are formed during the singulation of the conversion element. For example, the side surfaces in the region of the conversion layer comprise a different type of traces of a singulation process than the side surfaces in the region of the sapphire substrate. For example, in the region of the conversion layer, the side surfaces comprise traces of a sawing process and in the region of the sapphire substrate, the side surfaces comprising traces of a laser separation process.

According to one embodiment, the conversion layer comprises at least one of the phosphors from one of the following groups:

Group 1: Garnets: yttrium aluminum garnet (YAG) doped with cerium (CE), gallium (Ga) or gadolinium (GD), lutetium aluminum garnet (LuAG);

Group 2: Nitrides doped with europium (EU) or oxinitrides doped with EU;

Group 3: CaAlSiN₃:Eu (CASN doped with EU) or (Sr,Ca)AlSiN₃:Eu (SCASN doped with EU). In particular, the conversion layer comprises a mixture of phosphors formed with oxides and nitrides. For example, the phosphor comprises particles that comprise an average diameter of at least 200 nm. In particular, the phosphors are non-sintering phosphors. In other words, the phosphors are not suitable to be processed by means of a sintering process.

According to one embodiment, a concentration of the phosphor in the conversion layer is at least 50-60%. Advantageously, the particularly high concentration of the phosphor in the conversion layer enables a particularly efficient conversion of electromagnetic radiation.

A method for producing a light-emitting semiconductor device is further specified. In particular, the method can be used to produce a light-emitting semiconductor device comprising a conversion element described above. That is, all features disclosed for the light-emitting semiconductor device are also disclosed for the conversion element, and vice versa.

The light-emitting semiconductor device is, for example, a light-emitting diode which is configured to emit electromagnetic radiation in the visible wavelength range during intended operation. In particular, the light-emitting semiconductor device is configured to emit electromagnetic radiation of a white color location.

According to one embodiment, the method for producing the light-emitting semiconductor device comprises a method step d) in which semiconductor chips are provided. Each semiconductor chip comprises a radiating surface and is arranged on a common carrier. The semiconductor chips are, for example, LED chips which are configured to generate and emit electromagnetic radiation. In particular, at least a majority of the emitted electromagnetic radiation of the LED chips is emitted through their respective radiating surfaces during intended operation. For example, the semiconductor chips are provided to emit electromagnetic radiation in a wavelength range between 445 nm and 455 nm.

The carrier is, for example, a ceramic carrier which comprises contact structures for electrical contacting of the semiconductor chips. In particular, the carrier has the shape of a 4 inch wafer. By means of the electrical contact structures, each semiconductor chip can be contacted in an electrically conductive manner.

According to one embodiment, the method for producing a semiconductor device comprises a method step e) in which conversion elements are provided. In particular, the conversion elements are the conversion elements described above. For example, the conversion elements are configured to at least partially convert the radiation emitted by the semiconductor chips so that the light-emitting semiconductor device emits white light having a chromaticity coordinate in a CIE color space with cx=0.33 and cy=0.35.

According to one embodiment of the method for producing a light-emitting semiconductor device, the method comprises a method step f) wherein one of the conversion elements is arranged on each of the radiating surfaces, wherein the conversion layer faces the associated semiconductor chip. For example, the radiating surface is in each case completely covered, in particular at least 80% covered, by the conversion element assigned to the respective radiating surface. For example, the conversion elements are each firmly connected mechanically to the semiconductor chip by means of an adhesive layer. In particular, the side of the conversion element facing away from the semiconductor chip is formed with the sapphire substrate. In particular, the conversion layer can be arranged on a side of the conversion element facing the semiconductor chip. Advantageously, arranging the conversion layer on a side facing the semiconductor chip enables particularly efficient heat dissipation from the conversion element, since heat generated in the conversion element during intended operation can be dissipated in a particularly simplified manner via the semiconductor chip.

According to one embodiment of the method for producing a light-emitting semiconductor device, the method comprises a method step g) in which a cover foil is provided which covers the carrier and the conversion elements. The cover foil is arranged, for example, on the side of the conversion elements facing away from the carrier on a tool. In particular, the cover foil completely covers the carrier and is formed in a continuous manner, in particular in a simply connected manner. For example, the cover foil is attached to a surface of the tool by deep drawing. The cover foil is, for example, a flexible foil which adapts to the surface contour when placed on the carrier, the semiconductor chips and the conversion elements. The foil preferably comprises a polymer, in particular polyethylene terephthalate (PET), ethylene tetrafluoroethylene copolymer (ETFE), polytetrafluoroethylene (PTFE), polyvinyl chloride (PVC).

According to one embodiment of the method for producing a light-emitting semiconductor device, the method comprises a method step h) in which the cover foil is pressed onto the side of the conversion elements facing away from the semiconductor chips. For example, a pressure is applied to the side of the foil facing away from the conversion element, which is transferred to the conversion elements by means of the foil. The pressure can be applied to the cover foil by means of the tool.

According to one embodiment of the method for producing a light-emitting semiconductor device, the method comprises a method step i) in which a potting compound is brought in between the cover foil and the carrier, wherein the potting compound completely laterally surrounds each of the semiconductor chips and the conversion elements. In other words, the conversion elements and the semiconductor chips are each completely surrounded by the potting compound in the lateral direction, which is parallel to their main extension planes, wherein, for example, the side surfaces of the semiconductor chips and/or the conversion elements are partially free of the potting compound. In particular, the cover foil completely covers the side of the conversion elements facing away from the semiconductor chips in each case, so that the potting compound does not cover the conversion elements on their side facing away from the semiconductor chips in each case. For example, the side of the conversion elements facing away from the semiconductor chips is free of the potting compound.

In particular, the potting compound is brought in by means of an injection molding process. The potting compound comprises, for example, a polymer material, in particular a silicone or epoxy. Particles of titanium oxide (TiO2) or silicon dioxide (SiO2) may be brought in the potting compound. The potting compound is cured, for example, first at 180° C. and then at 150° C. for four hours. The potting compound may be formed with a reflective material.

According to one embodiment of the method for producing a light-emitting semiconductor device, the method comprises a method step j) in which the cover foil is removed and the potting compound and the carrier are severed to form individual light-emitting semiconductor devices.

For example, the potting compound and the carrier are severed by means of a sawing process. Each resulting light-emitting semiconductor device may comprise at least one semiconductor chip. In particular, each light-emitting semiconductor device comprises a plurality of semiconductor chips.

According to one embodiment, the method for producing the light-emitting semiconductor device comprises the following method steps: (d) Providing semiconductor chips, wherein the semiconductor chips comprise radiating surfaces and are arranged on a common carrier; (e) providing conversion elements according to one of the preceding embodiments; (f) arranging one of the conversion elements on each radiating surface, wherein the conversion layer faces the associated semiconductor chip; (g) providing a cover foil covering the carrier and the conversion elements; (h) pressing the cover foil onto the side of the conversion elements facing away from the semiconductor chips; (i) bringing in a potting compound between the cover foil and the carrier, wherein the potting compound completely laterally surrounds each semiconductor chip; and(j) Removing the cover foil and severing the potting compound and the carrier to form individual light-emitting semiconductor devices.

According to one embodiment of the method for producing a light-emitting semiconductor device, in method step h) the cover foil is pressed onto each conversion element with a weight of at least 200 g. In particular, the cover foil is pressed onto each conversion element with a weight of at least 500 g. For example, each conversion element comprises an area of 1 mm2, in particular 2 mm2, on the side facing away from the semiconductor chips. In particular, the weight with which the cover foil is pressed onto each conversion elements is so great that the cover foil remains in direct contact with the side facing away from the semiconductor chips in method step i) when the potting compound is brought in.

According to an embodiment of the method for producing a light-emitting semiconductor device, the potting compound is brought in at a pressure of at least 30 bar in method step i). In particular, the potting compound is brought in at a pressure between 30 and 150 bar, preferably between 60 and 120 bar.

In particular, any air-filled regions between the carrier and the cover foil are completely filled with the potting compound. For example, an underpressure is generated between the cover foil and the carrier, so that bringing in the potting compound is simplified. After bringing in the potting compound, for example, a surface of the potting compound facing away from the carrier is completely in direct contact with the cover foil. For example, the shape of the surface of the potting compound is predetermined by means of the cover foil.

A light-emitting semiconductor device is further specified. In particular, the light-emitting semiconductor device can be produced by the method for producing a light-emitting semiconductor device described above. That is, all features disclosed for the light-emitting semiconductor device are also disclosed for the method for producing the light-emitting semiconductor device, and vice versa.

According to one embodiment, the light-emitting semiconductor device comprises a semiconductor chip comprising a radiating surface and a conversion element as described above, wherein the conversion element is cohesively attached to the radiating surface. In particular, the semiconductor chip is a previously described semiconductor chip. For example, the conversion element is attached to the radiating surface by means of an adhesive layer.

According to this embodiment, the conversion layer is arranged on a side of the conversion element facing the semiconductor chip, and the semiconductor chip and the conversion element are laterally surrounded by a potting compound, wherein the conversion element projects beyond the potting compound in a vertical direction. The lateral direction is along the main extension plane of the sapphire substrate, and the vertical direction is perpendicular to the main extension plane of the sapphire substrate.

In particular, the conversion element projects beyond the potting compound on a side facing away from the semiconductor chip. According to one embodiment, the conversion element projects beyond the potting compound by at least 10 μm, preferably by at least 20 μm. For example, the conversion element projects beyond the potting compound in the vertical direction by the thickness of the cover foil. The thickness of the cover foil may be at least 10 μm, in particular at least 20 μm.

According to one embodiment of the light-emitting semiconductor device, the semiconductor chip is electrically conductively contacted by means of a bonding wire, wherein the bonding wire is completely embedded in the potting compound, and the conversion element projects beyond the bonding wire in the vertical direction. For example, the thickness of the conversion element determines how far the potting compound protrudes beyond the semiconductor chip in the vertical direction. For example, the thickness of the conversion element is selected so that the conversion element projects beyond the bonding wire by at least 20 μm. Advantageously, complete embedding of the bonding wire in the potting compound enables a particularly reliable light-emitting semiconductor device.

### BRIEF DESCRIPTION OF THE DRAWINGS

Further advantages and advantageous embodiments and further developments of the method for producing conversion elements, the conversion element, the method for producing a light-emitting semiconductor device and the light-emitting semiconductor device will become apparent from the exemplary embodiments described below in association with the figures.

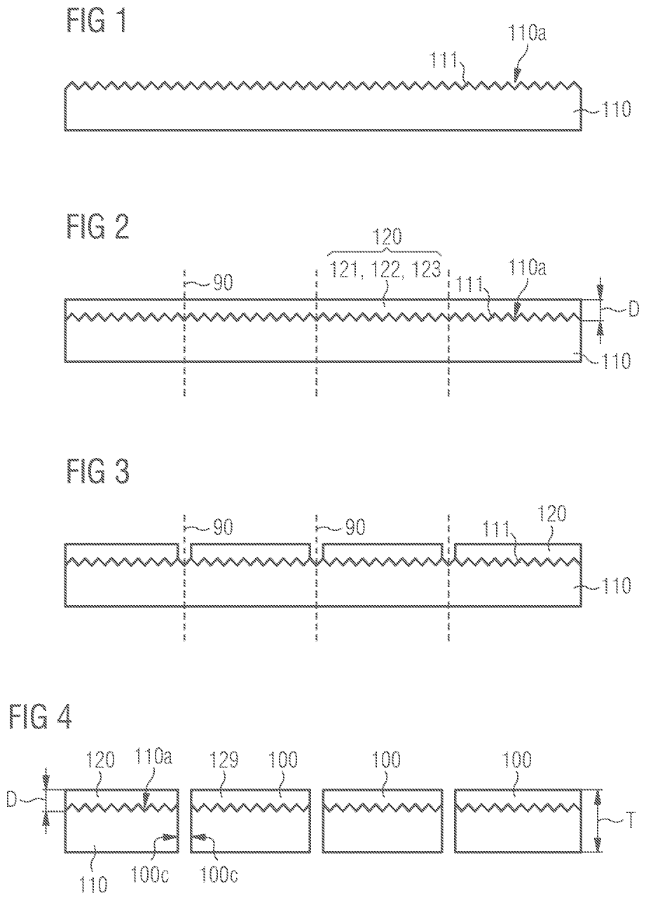

In FIGS. 1, 2 and 3 schematic sectional views of different stages during a method for producing conversion elements according to an exemplary embodiment are shown.

In FIG. 4 a schematic sectional view of conversion elements according to an exemplary embodiment is shown.

In FIGS. 5, 6 and 7 schematic sectional views of different stages during a method for producing a light-emitting semiconductor device according to an exemplary embodiment are shown.

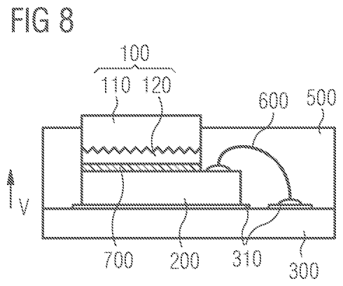

In FIG. 8 a schematic sectional view of a light-emitting semiconductor device according to an exemplary embodiment is shown.

In the exemplary embodiments and figures, similar or similarly acting constituent parts are provided with the same reference symbols. The elements illustrated in the figures and their size relationships among one another should not be regarded as true to scale. Rather, individual elements may be represented with an exaggerated size for the sake of better representability and/or for the sake of better understanding.

### DETAILED DESCRIPTION OF ILLUSTRATIVE EMBODIMENTS

FIG. 1 shows a schematic sectional view of a sapphire substrate 110 for the production of conversion elements described herein. The sapphire substrate 110 is provided in a method step a) of the method for producing conversion elements. The sapphire substrate includes protrusions 111 that are arranged on a first main surface 110a of the sapphire substrate 110. In the present embodiment, the protrusions 111 are each cone-shaped. Alternatively, the protrusions 111 may be pyramid-shaped or dome-shaped.

FIG. 2 shows a schematic sectional view of a sapphire substrate 110 and a conversion layer 120 according to the method steps a) and b) described herein of the method for producing conversion elements according to an exemplary embodiment. To form the conversion layer 120, a first sublayer 121, a second sublayer 122, and a third sublayer 123 are arranged on the first main surface 110a of the sapphire substrate. The sublayers 121, 122, 123 are sequentially deposited on each other by spraying. The sublayers 121, 122, 123 completely cover the first main surface 110a of the sapphire substrate 110.

The conversion layer 120 comprises a thickness D of 30 μm. Alternatively, the thickness D may be 10 μm. In particular, the thickness D is the maximum thickness of the conversion layer 120 perpendicular to its main extension plane. The conversion layer 120 completely covers the protrusions 111 on the first main surface 110a, such that the conversion layer 120 comprises a planar surface on a side facing away from the sapphire substrate 110.

FIG. 3 shows a schematic sectional view of a stage of the method for producing conversion elements in method step c), in which the sapphire substrate 110 and the conversion layer 120 are separated into a plurality of conversion elements 100. In this process, the conversion layer 120 and the sapphire substrate 110 are separated along imaginary separation lines 90.

In this process, the sapphire substrate and the conversion layer are separated by means of different separation methods. The conversion layer is severed by means of a sawing process. Alternatively, the conversion layer 120 may be severed means of an etching process. In a subsequent method step, the sapphire substrate 110 is severed along the separation lines 90 by means of a laser cutting process, for example, so that individual conversion elements 100 are formed. When the sapphire substrate 110 and the conversion layer 120 are separated, a plurality of conversion elements 100 are formed, each comprising side surfaces 110c.

FIG. 4 shows a schematic sectional view of conversion elements described herein according to an exemplary embodiment. Each conversion element 100 comprises a sapphire substrate 110 and a conversion layer 120 arranged on the first main surface 110a of the sapphire substrate 110. The conversion layer 120 comprises a thickness D of 30 μm. Perpendicular to the main extension plane of the sapphire substrate 110, each conversion element comprises a thickness T of at least 120 μm. In particular, in the vertical direction, perpendicular to their main extension plane, each conversion element 100 comprises a thickness T of at least 150 μm. The individual conversion elements 100 comprise traces of a singulation process on their side surfaces 100c. The traces are, for example, traces of a sawing process and/or a laser severing process.

The conversion layer comprises at least one of the phosphors from one of the following groups:

Group 1: Garnets: yttrium aluminum garnet (YAG) doped with cerium (CE), gallium (Ga) or gadolinium (GD), lutetium aluminum garnet (LuAG);

Group 2: Nitrides doped with europium (EU) or oxinitrides doped with EU;

Group 3: CaAlSiN₃:Eu (CASN doped with EU) or (Sr,Ca)AlSiN₃:Eu (SCASN doped with EU). The phosphor 129 is present at a concentration of at least 50% to 60% in the conversion layer 120.

FIG. 5 shows in a schematic sectional view a stage of a method described herein for producing a light-emitting semiconductor device 1 according to an exemplary embodiment. The view shown in FIG. 5 shows an arrangement after method steps d), e) and f). In method step d), semiconductor chips 200 are provided, wherein the semiconductor chips 200 comprise radiating surfaces 200a and are arranged on a common carrier 300. The carrier 300 is, for example, a ceramic carrier with contact structures 310 for electrical contacting of the semiconductor chips 200. By means of bonding wires 600, each semiconductor chips 200 is electrically conductively contacted.

In method step e), conversion elements 100 are provided. In particular, the conversion elements 100 are produced in the method steps a) to c) described above.

In a method step f), one of the conversion elements 100 is arranged on each of the radiating surfaces 200a, wherein the conversion layer 120 faces the associated semiconductor chip 200. The conversion elements 100 are each mechanically firmly bonded to a semiconductor chip 200 by means of an adhesive layer 700. For example, the conversion elements 100 cover at least 80% of the radiating surface 200a.

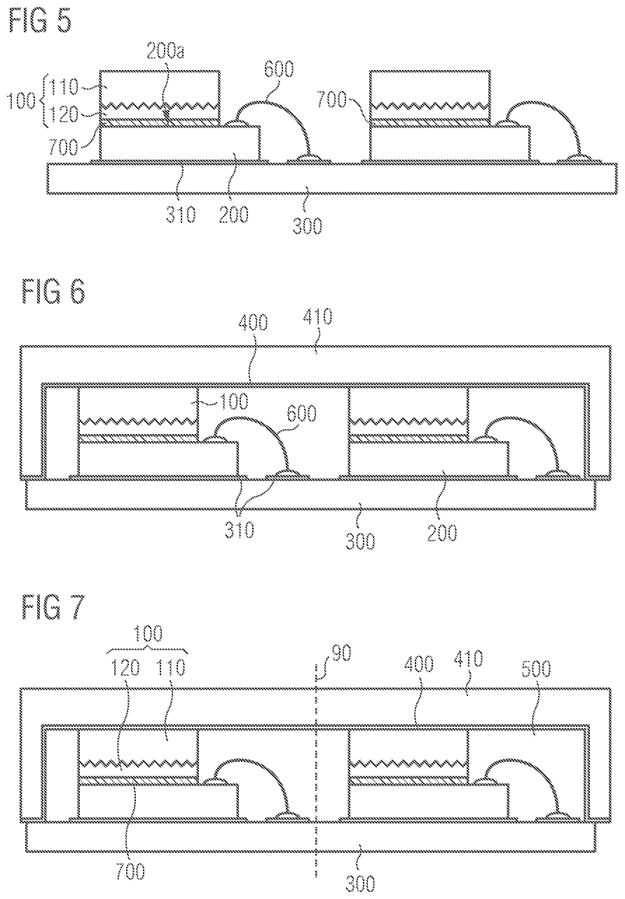

FIG. 6 shows in a schematic sectional view a stage of a method described herein for producing light-emitting semiconductor devices according to method step g) according to an exemplary embodiment. In method step g), a cover foil 400 is provided which covers the carrier 300 and the conversion elements 100. The foil is attached to a surface of a tool 410 by deep drawing. In a method step h), the cover foil 400 is pressed onto the side of the conversion elements 100 facing away from the semiconductor chips 200 by means of the tool 410. In this process, a weight force of at least 200 g acts on each of the sides of the conversion elements 100 facing away from the semiconductor chips 200. For example, the conversion elements comprise an area of at most 2 mm2, preferably at most 1 mm2, on a side facing away from the semiconductor chip 200.

FIG. 7 shows in a schematic sectional view a stage of the method for producing a light-emitting semiconductor device 1 according to an exemplary embodiment. In method step i), a potting compound 500 is brought in between the cover foil 400 and the carrier 300, wherein the potting compound 500 completely surrounds each semiconductor chip 200 in lateral directions. Furthermore, the potting compound 500 also completely surrounds each conversion elements 100 in lateral directions. For example, the lateral directions are parallel to the main extension plane of the carrier 300.

The potting compound 500 is brought in between the carrier 300 and the cover foil 400 by means of an injection molding process. In this process, the potting compound 500 is brought in at a pressure between 30 bar and 150 bar. During the bringing in of the potting compound 500, the cover foil 400 is pressed onto the side of the conversion elements 100 facing away from the semiconductor chips 200, so that the potting compound 500 does not cover the conversion elements 100. In particular, the side of each conversion element 100 facing away from the semiconductor chip 200 is free of the potting compound 500.

In a subsequent method step j), the cover foil 400 is removed and the potting compound 500 and the carrier 300 are severed to individual light-emitting semiconductor devices 1. The carrier 300 and the potting compound 500 are severed along the imaginary separation line 90, so that each light-emitting semiconductor device 1 comprises exactly one light-emitting semiconductor chip 200. Alternatively, the individual light-emitting semiconductor devices 1 may each comprise a plurality of semiconductor chips 200.

FIG. 8 shows a schematic sectional view of a light-emitting semiconductor device 1 described herein according to an exemplary embodiment. The light-emitting semiconductor device 1 comprises a semiconductor chip 200 with a radiating surface 200a and a conversion element 100. The conversion element 100 is cohesively attached to the radiating surface 200a by means of an adhesive layer 700. The conversion layer 120 of the conversion element 100 is arranged on a side of the conversion element 100 facing the semiconductor chips 200.

The semiconductor chip 200 and the conversion element 100 are each completely surrounded by the potting compound 500 in a lateral direction, wherein the conversion element 100 projects beyond the potting compound 500 in a vertical direction V. For example, the conversion element 100 overhangs the potting compound 500 by at least 10 μm preferably by at least 20 μm. The semiconductor chip 200 is electrically conductively contacted by means of a bonding wire 600, wherein the bonding wire 600 is completely embedded in the potting compound 500, and the conversion element 100 projects beyond the bonding wire 600 in the vertical direction V.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

1.-17. (canceled)

18. A method for producing conversion elements, the method comprising:
providing a sapphire substrate;
forming a conversion layer on a first main surface of the sapphire substrate; and
separating the sapphire substrate and the conversion layer into a plurality of conversion elements.

19. The method according to the claim 18, wherein forming the conversion layer comprises applying at least three sublayers to each other by spraying.

20. The method according to claim 18, wherein separating the sapphire substrate and the conversion layer comprises separating the sapphire substrate and the conversion layer by different separation processes.

21. The method according to claim 20, wherein separating the sapphire substrate comprises separating the sapphire substrate by laser cutting, and wherein separating the conversion layer comprises separating the conversion layer by sawing.

22. The method according to claim 18, wherein forming the conversion layer comprises applying the conversion layer with a maximum thickness of 30 μm.

23. The method according to claim 18, wherein the first main surface of the sapphire substrate comprises protrusions periodically arranged along the first main surface.

24. A conversion element comprising:
a sapphire substrate; and
a conversion layer arranged on a first main surface of the sapphire substrate,
wherein the conversion layer comprises a maximum thickness of 30 μm.

25. The conversion element according to claim 24, wherein the conversion element comprises a thickness of at least 120 μm.

26. The conversion element according to claim 24,
wherein the conversion element comprises side surfaces, and
wherein the side surfaces comprise traces of a singulation process.

27. The conversion element according to claim 24, wherein the conversion layer comprises at least one phosphor from yttrium aluminum garnet (YAG) doped with cerium (CE), gallium (Ga) or gadolinium (GD), or lutetium aluminum garnet (LuAG); nitrides doped with europium (EU) or oxinitrides doped with EU; or CaAlSiN₃:Eu (CASN doped with EU) or (Sr,Ca)AlSiN₃:Eu (SCASN doped with EU).

28. The conversion element according to claim 27, wherein a concentration of the phosphor in the conversion layer is between 50% and 60% inclusive.

29. A method for producing a light-emitting semiconductor device, the method comprising:
providing semiconductor chips, wherein each semiconductor chip comprises a radiating surface, and wherein the semiconductor chips are arranged on a common carrier;
providing conversion elements according to claim 24;
arranging one of the conversion elements on each radiating surface, wherein the conversion layer faces an associated semiconductor chip;
providing a cover foil covering the carrier and the conversion elements;
pressing the cover foil onto a side of the conversion elements facing away from the semiconductor chips;
providing a potting compound between the cover foil and the carrier, wherein the potting compound completely laterally surrounds each semiconductor chip; and
removing the cover foil and severing the potting compound and the carrier to form individual light-emitting semiconductor devices.

30. The method according to claim 29, wherein pressing the cover foil comprises pressing the cover foil onto each conversion element with a weight of at least 200 grams.

31. The method according to claim 29, wherein providing the potting compound comprises providing the potting compound with a pressure of at least 30 bar.

32. A light-emitting semiconductor device comprising:
a semiconductor chip with a radiating surface; and
the conversion element according to claim 24,
wherein the conversion element is cohesively attached to the radiating surface,
wherein the conversion layer is arranged on a side of the conversion element facing the semiconductor chip,
wherein the semiconductor chip and the conversion element are laterally surrounded by a potting compound, and
wherein the conversion element projects beyond the potting compound in a vertical direction.

33. The light-emitting semiconductor device according to the claim 32, wherein the conversion element projects beyond the potting compound by at least 10 μm.

34. The light-emitting semiconductor device according to claim 32,
wherein the semiconductor chip is electrically conductively contacted a bonding wire,
wherein the bonding wire is completely embedded in the potting compound, and
wherein the conversion element projects beyond the bonding wire in the vertical direction.
